(19) United States
(12) Patent Application Publication
(10) Pub. No.: US 2003/0174072 A1
(43) Pub. Date: Sep. 18, 2003

(54) Systems and methods employing changeable touch-key

(76) Inventor: Tahl Salomon, Sudbury, MA (US)

Correspondence Address: FOLEY HOAG, LLP, PATENT GROUP, WORLD TRADE CENTER WEST, 155 SEAPORT BLVD, BOSTON, MA, 02110, US

(21) Appl. No.: 10/386,265

(22) Filed: Mar. 11, 2003

Related U.S. Application Data
(60) Provisional application No. 60/363,111, filed on Mar. 11, 2002.

(51) Int. Cl. H03M 11/00; H03K 17/94

(52) U.S. Cl. 341/22; 341/31

(57) ABSTRACT

Methods and systems including a key-using device having at least one key and a microprocessor, the at least one key comprising a flexible display module, the at least one key in communications with the microprocessor, where the microprocessor includes instructions for controlling the appearance of the flexible display module based on at least one of an application and a user profile. The flexible display module can include electronic paper and/or flexible organic optical light emitting devices (FOLEDs). The communications between the microprocessor the flexible display module can be wired and/or wireless.

### CLAIM OF PRIORITY

This application claims priority to U.S. Ser. No. 60/363,111, entitled “Key Having Changeable Properties,” and filed on Mar. 11, 2002, naming Tahl Salomon as inventor, the contents of which are herein incorporated by reference in their entirety.

### BACKGROUND

(1) Field

The disclosed methods and systems relate generally to touch keys such as touchpad keys, and more particularly to touchpad keys that have configurable operational characteristics and physical attributes.

(2) Description of Relevant Art

Touchable keys, individually or as part of keyboards, keypads or other arrays of touch-keys, are used in a range of electrical and electronic devices and can generally be an input tool to allow an operator of such device to have ease of data entry into the device and/or control of the device and/or a system associated with the device. Generally, a key is permanently labeled with regard to its particular operational characteristic and physical appearance.

Some physically small devices that rely on touch keys such as mobile and/or hand held devices, portable computers, cellular phones, Personal Digital Assistants (PDAs), pagers, portable Internet devices, electronic dictionaries, remote controls, or calculators, can be disadvantaged by their size that may allow for a limited number of keys. Accordingly, some keys can maintain multiple operational characteristics and/or functions. To account for its multi functionality, a key can often be labeled with a variety of signs, symbols and text, that can be confusing in providing an abundance of information and/or insufficient information regarding the key.

Alternately, having too many keys may also prove to be a disadvantage, as key panels may grow too large, be hard to master, and/or be replete with keys that are seldom used.

### SUMMARY

The disclosed methods and systems include a system having a key-using device, the key-using device having one or more keys and a microprocessor, the key(s) including a flexible display module and the key(s) in communications with the microprocessor, where the microprocessor includes instructions for controlling the appearance of the flexible display module based on an application and/or a user profile. The application can include executable instructions that can reside on the microprocessor, and/or instructions that reside on one or more distinct second microprocessors that can be in communications with the microprocessor. The flexible display module can include one or more of electronic paper and/or an optical organic light emitting device (OLED). The OLED can be a flexible OLED, for example.

As provided herein, a key-using device can include a device having a key and/or a touch pad and can include, for example, devices that are and/or include a keyboard, a keypad, a computer, a cellular phone, a hand held computer, a PDA, a portable Internet device, a pager, a remote control, and a calculator.

The key(s) can include a light source and/or a transparent cover. The instructions to control the appearance of the flexible display module can include instructions to provide a preset value for display on the module. The present value can be based on an application and/or a user setting. Accordingly, the instructions to control include can include instructions to display at least at least one character, text, at least one sign, at least one icon, at least one symbol, at least one image, and/or a blank image.

The communications can be wired and/or wireless, and can use one or more communications protocols and/or one or more networks including the internet.

The system can also include microprocessor instructions for controlling the operational characteristics of the key(s). Some operational characteristics can include, for example, quick dial, display of a menu, generate one or more telephone tones, mute, hold, conference, intercom, speaker, perform a computation and/or calculation, provide/transmit one or more audio and/or electrical signals, and/or execute a set of instructions that can include a macro and/or one or more microprocessor-executable instructions. As provided herein, operational characteristics can thus be understood to include a one or more actions to obtain a result, where an action can be electrical, audible, wired, wireless, and/or can include one or more microprocessor-executable instructions.

The user profile can be associated with a user name, password, personal identification number (PIN), and/or can otherwise be associated with identity information such as biometric data. A user can thus log-in or otherwise be identified and/or authenticated, where such identification and/or authentication can cause a retrieval of an associated user profile that can further be associated with preset and/or default settings for one or more of the key(s), where such presets can include display and/or operational characteristics. As provided herein, the preset and/or default settings may additionally and/or optionally be based on an application. In some embodiments, an application can be associated with the user profile such that the preset and/or default settings can be based on the application and the user profile. In some embodiments, one or more of the keys may not be altered via preset and/or default settings.

Other objects and advantages will become apparent hereinafter in view of the specification and drawings.

### BRIEF DESCRIPTION OF THE DRAWINGS

FIG. 1 illustrates an expanded view of a flexible display module, a conventional key, and a display driver processing module;

FIG. 2 shows a flexible display module, a conventional key, and a display driver processing module;

FIG. 3 illustrates an expanded view of a flexible display module, a conventional key, and a display driver processing module;

FIG. 4 shows a flexible display module, a conventional key, and a display driver processing module;

FIG. 4A illustrates an expanded view of a flexible display module, a conventional key, a display driver processing module, a transparent cover, and a light emitting source;

FIG. 4B shows a flexible display module, a conventional key, a display driver processing module, a transparent cover, and a light source;

FIG. 5 shows a keyboard having flexible display keys;

FIG. 6 is an enlarged section of a keyboard according to FIG. 5, showing an example of numbers and upper case letters displayed on the flexible display keys;

FIG. 7 is an enlarged section of the keyboard of FIG. 5, showing an example of various characters and lower case letters displayed on the display keys;

FIG. 8 is an enlarged section of the keyboard of FIG. 5, showing an example of numbers and special characters;

FIG. 9 shows a cellular phone having flexible display keys;

FIG. 10 is an enlarged section of the cellular phone of FIG. 9, showing an example of alphabetical letters displayed on the flexible display keys;

FIG. 11 is an enlarged section of the cellular phone of FIG. 9, showing an example of various menu choices displayed on the display keys; and

FIG. 12 is an enlarged section of the cellular phone of FIG. 9, showing an example of stored names for quick dial.

### DESCRIPTION

To provide an overall understanding, certain illustrative embodiments will now be described; however, it will be understood by one of ordinary skill in the art that the systems and methods described herein can be adapted and modified to provide systems and methods for other suitable applications and that other additions and modifications can be made without departing from the scope of the systems and methods described herein.

Unless otherwise specified, the illustrated embodiments can be understood as providing exemplary features of varying detail of certain embodiments, and therefore, unless otherwise specified, features, components, modules, and/or aspects of the illustrations can be otherwise combined, separated, interchanged, and/or rearranged without departing from the disclosed systems or methods. Additionally, the shapes and sizes of components are also exemplary and unless otherwise specified, can be altered without affecting the disclosed systems or methods.

The present disclosure includes a key-using device that can be understood herein as a device that includes at least one key or button, including but not limited to a keyboard, phone, or another device having a touchpad, such device elements to be referred to herein collectively as a key(s), where the operational and visible characteristics of the key can be varied and/or variable. For example, a key's displayed information can be changed based on an application and/or a user profile. The key-using device can also include a processor that can be referred to herein as the main processor. Such processor can be physically incorporated with the key, and/or communicate with the key remotely using wired and/or wireless communications techniques and/or protocols.

The disclosed keys can also include a display module including a flexible display, where a flexible display can be understood herein to be a display that can be varied using, for example, electronic paper and/or flexible organic light emitting device (FOLED), where such display can be coupled with a key's mechanical structure such that the key's operational characteristics can be altered and displayed accordingly.

Those of ordinary skill in the art will understand that electronic paper can be understood to be an electronic imitating wood-pulp paper's properties of being thin, flexible, reflective. Electronic paper generally does not require additional power to retain an image, and generally has the ability to update itself and generate new images. Such updating can be performed using a processor or other electronic control. In addition, electronic paper can also include other characteristics such as a wide viewing angle, a high contrast, and easy readability in different lighting environments. Electronic paper can display data using different pigmented positively and negatively charged microcapsules (or beads) and circuitry that create pixel patterns that can be controlled by a display driver. “Electronic paper” as provided herein, can be understood to include products known as “electric paper”, “digital paper”, “SmartPaper”, “Gyricon technology”, “e-ink”, “electronic ink”, “e-paper”, “electrophoretic ink”, or “radio paper”, and other technologies having other names, yet sharing the same properties.

FOLED (flexible organic light emitting device) can be understood by those in the art to be an organic light emitting device (OLED) built on a flexible base material, such as clear plastic film or reflective metal foil. FOLEDs use circuitry that creates pixel patterns to generate light and form information. These displays can be comparatively thinner, lighter, more durable, and less expensive to produce than the traditional glass-based alternatives. “Flexible display” as provided herein, can be understood to include products known as “FOLED”, or “electronic paper”, and other technologies having other names, yet sharing the same properties. Further, references herein to FOLED can include references to other OLED, such as TOLED (transparent), SOLED (stacked), and others, with such examples provided for illustration and not limitation.

Accordingly, unlike glass-based alternative displays such as LCDs, the disclosed flexible displays can be built on a flexible base material, for example, such as plastic, that can be conformed, bent, and/or rolled to allow for a variety of display shapes that can further be flexible. In one example, the keys can be curve-shaped. Such materials may also provide for varying display widths, and can provide for flexible displays that are thin, light-weight, robust, cost-effective, and consume comparatively low amounts of power to extend battery life in, for example, portable devices.

The present disclosure includes a key-using device having one or more keys that can include one or more flexible displays. The one or more keys can be controlled by a display driver processing module. The display driver processing module can be in communications with the main processor. Based on, for example, a user profile, a selection or change in an application, and/or other data or information, the display driver processing module can cause a key's operational and/or visible features and/or characteristics to change.

FIG. 1 illustrates an expanded view of a flexible display module 1, a key 2, and a display driver processing module 3 which is illustrated with an electrical connection 4 to the flexible display module 1, although such connection can be wired and/or wireless. In the embodiment shown, the flexible display module 1 can be incorporated into a key 2 such as that typical of a computer keyboard, however a key, button, touchpad, etc., referred to herein collectively as a key, on another device can be adapted for the systems and methods provided herein, including but not limited to keys on cellular or other telephones, PDAs, portable Internet devices, pagers, and other electronic devices that include at least one key or button.

As provided herein, the key-using device can also include a processor (not shown) that can be referred to herein as the main processor. The main processor can allow the key-using device to operate in the manner typical known by a user of the key-using device.

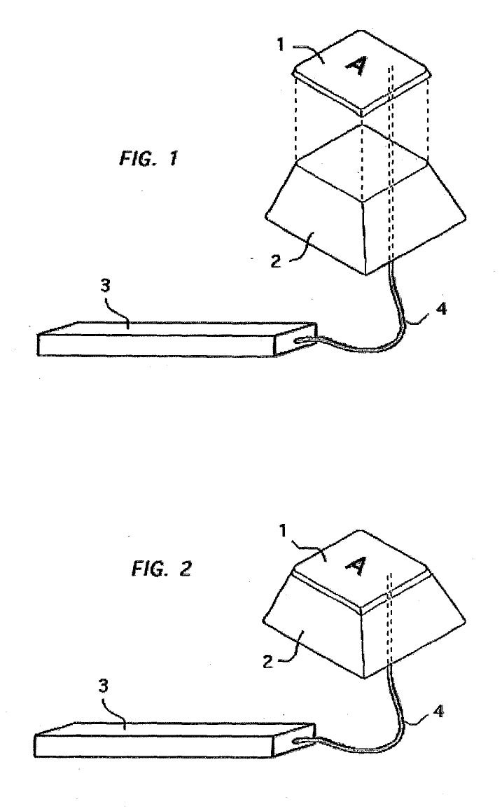

FIG. 2 shows the flexible display module 1 and a key 2 as they are bonded together. Such bonding can be performed using suitable materials such as an epoxy or other adhesive, although such bonding materials are merely illustrative. It can be understood that the illustrated display driver processing module 3 can be in communications with one or more flexible display modules 1 for one or more keys 2 such that one display driver processing module 3 can control one, several, and as many as all of the display-keys of a key-using device. In the illustrated embodiment, a wired electrical connection 4 is shown between the display driver processing module 3 and the flexible display module 1 that is integrated with the key 2. In an embodiment of a wired connection 4, the user may not visibly detect the connection. As provided herein, additionally and optionally, the connection and/or communicative link 4 between the display driver processing module 3 and a key 2 can be wireless.

The display driver processing module 3 can also be in communications, wired or wireless, with the main processor. Accordingly, the display driver processing module 3 can receive information related to the application in which a user is active, and cause an appropriate signal to be provided to a key based on the application and other information. For example, the display driver processing module 3 can utilize information including a user's profile that could include preferences for various applications. Based on the selected application and the user's profile, a signal can be provided to a key 2 to display a corresponding key label. Similarly, the main processor can be provided with information to provide the associated operational characteristics/interpretations to the key.

Those with ordinary skill in the art will recognize that the displayed methods and systems can include, for example, one or more databases that can include the different key display configurations and user profile data. The display driver processing module 3 thus can include a processor that can access, for example, the one or more databases. The display driver processing module 3 can also includes instructions for causing the processor to perform the features attributed herein to the display driver processing module 3.

A display indicia for a key 2 can remain until such time that a new signal is provided to alter the key. As indicated previously, a key can change because a different application is being used, or a function is activated, or some other control activity occurred to change the key 2. A key 2 can have a default value that can be based on a preset configuration.

In one embodiment, the display processing module 3 and the main processor can be a single processor.

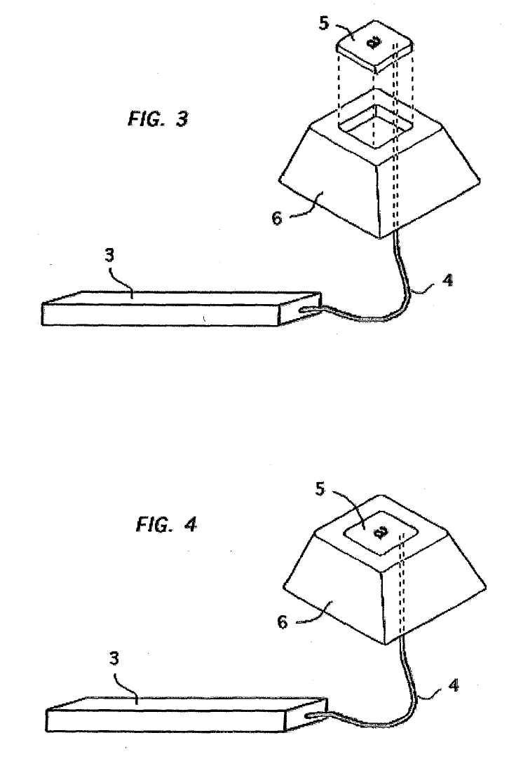

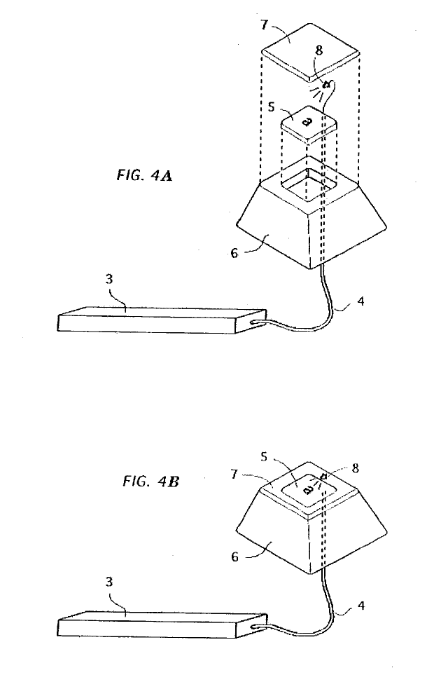

FIG. 3 illustrates an expanded view of a flexible display module 5, a key 6, and a display driver processing module 3 which can be electrically connected 4 to the flexible display module 5. FIG. 4 shows a different embodiment for combining the flexible display module 5 and the key 6. As illustrated in FIG. 4, the flexible display module 5 can be imbedded in the key 6 and can utilize a portion of the top surface of the key.

FIG. 4A illustrates an expanded view of the flexible display module 5, the key 6, a transparent cover 7, a light source 8, and the display driver processing module 3 that can be electrically connected 4 to the flexible display module 5. As provided herein, such electrical connections 4 in the illustrated embodiments can be wired and/or wireless.

FIG. 4B shows an embodiment for combining the flexible display module 5, the key 6, the transparent cover 7, and the light source 8. As illustrated in FIG. 4B, the transparent cover can cover and/or be placed on top of the flexible display module 5 and the light source 8, and the light source 8 can be located to illuminate the flexible display module. Those of ordinary skill will understand that variations of the illustrated embodiments can be made. For example, with reference to FIG. 4B, some embodiments may not include the cover 7 and/or the light source 8.

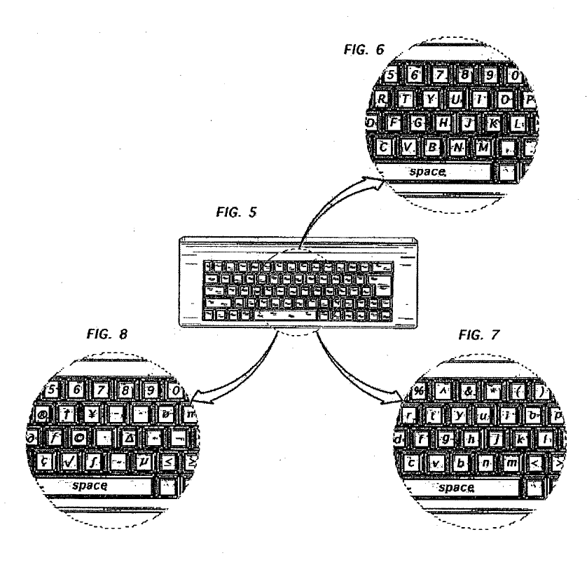

FIGS. 5 and 9 are illustrative examples of key-using devices having flexible display-keys. FIG. 5 shows a keyboard that includes flexible display-keys, while FIG. 9 shows a cellular phone that includes flexible display-keys. FIGS. 6-8 are enlarged sections of the keyboard of FIG. 5 that show an example of different indicia displayed on the same flexible display keys at different times in an application, and/or as a different application is used. The FIG. 6 keys show numbers and upper case letters, while the FIG. 7 keys display various characters and lower case letters. The FIG. 8 keys display numbers and special characters.

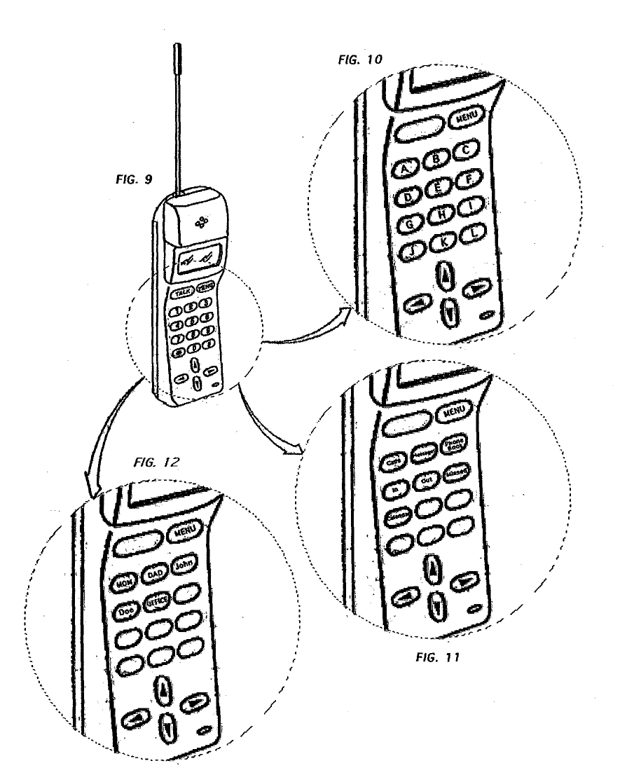

FIGS. 10-12 are enlarged sections of the cellular phone of FIG. 9 that show examples of different indicia displayed on the flexible display keys at different times in an application, and/or or as a new application is being used, for example. Those of ordinary skill will understand, as provided herein, that other criteria (e.g., user profile) can determine key appearance and operational characteristics. Accordingly, for the same keys on the cellular phone, the FIG. 10 keys show alphabetical letters, the FIG. 11 keys display various menu choices, while the configuration of FIG. 12 shows stored names for quick dial.

Disclosed herein is thus a key or button that can have at least one flexible display module to allow the visible properties of the key to change. A key-using device that can be a device having one or more keys can include a display driver processing module that can be in wired or wireless communications with the one or more keys of the key using device. Based on, for example, a selected application and/or a user profile, the display driver processing module can cause the key's displayed and/or operational properties to change. Similarly, the display driver processing module can communicate with the key-using device processor to allow the altered key properties to be interpreted. Keys can display characters, text, signs, icons, symbols, images, blank screens/images, and/or other information. When a key is not relevant or useful in a given application, the key can be blank. A key can include a clear and transparent cover for protection of the display module. In some embodiments, a light source can illuminate the keys. The flexible display module can be bonded to or imbedded on top of said key to at least partially cover the top surface of said key. An optional clear and transparent and/or translucent cover can be mounted on top of said display module to protect said display module.

The key, display module, and said processing module can generate and display information regarding its operational characteristics at a given time. As provided herein, the key can be any type of key, including a button or a switch, that is used in any electrical or electronic device. The key can be one or more of the keys of any conventional keyboard or keypad or of any electrical or electronic key-using device. This applies to, but is not restricted only to, devices such as conventional keyboards and keypads, portable computers, cellular phones, hand held computers, PDAs, portable Internet devices, pagers, electronic dictionaries, remote controls, and/or calculators.

What has thus been described are methods and systems including a key-using device having at least one key and a microprocessor, the at least one key comprising a flexible display module, the at least one key in communications with the microprocessor, where the microprocessor includes instructions for controlling the appearance of the flexible display module based on at least one of an application and a user profile. The flexible display module can include electronic paper and/or flexible organic optical light emitting devices (FOLEDs). The communications between the microprocessor the flexible display module can be wired and/or wireless.

The methods and systems described herein are not limited to a particular hardware or software configuration, and may find applicability in many computing or processing environments. The methods and systems can be implemented in hardware or software, or a combination of hardware and software. The methods and systems can be implemented in one or more computer programs, where a computer program can be understood to include one or more processor executable instructions. The computer program(s) can execute on one or more programmable processors, and can be stored on one or more storage medium readable by the processor (including volatile and non-volatile memory and/or storage elements), one or more input devices, and/or one or more output devices. The processor thus can access one or more input devices to obtain input data, and can access one or more output devices to communicate output data. The input and/or output devices can include one or more of the following: Random Access Memory (RAM), Redundant Array of Independent Disks (RAID), floppy drive, CD, DVD, magnetic disk, internal hard drive, external hard drive, memory stick, or other storage device capable of being accessed by a processor as provided herein, where such aforementioned examples are not exhaustive, and are for illustration and not limitation.

The computer program(s) can be implemented using one or more high level procedural or object-oriented programming languages to communicate with a computer system; however, the program(s) can be implemented in assembly or machine language, if desired. The language can be compiled or interpreted.

As provided herein, the processor(s) can thus be embedded in one or more devices that can be operated independently or together in a networked environment, where the network can include, for example, a Local Area Network (LAN), wide area network (WAN), and/or can include an intranet and/or the internet and/or another network. The network(s) can be wired or wireless or a combination thereof and can use one or more communications protocols to facilitate communications between the different processors. The processors can be configured for distributed processing and can utilize, in some embodiments, a client-server model as needed. Accordingly, the methods and systems can utilize multiple processors and/or processor devices, and the processor instructions can be divided amongst such single or multiple processor/devices.

The device(s) or computer systems that integrate with the processor(s) can include, for example, a personal computer(s), workstation (e.g., Sun, HP), personal digital assistant (PDA), handheld device such as cellular telephone, laptop, handheld, or another device capable of being integrated with a processor(s) that can operate as provided herein. Accordingly, the devices provided herein are not exhaustive and are provided for illustration and not limitation.

References to “a microprocessor” and “a processor”, or “the microprocessor” and “the processor,” can be understood to include one or more microprocessors that can communicate in a stand-alone and/or a distributed environment(s), and can thus can be configured to communicate via wired or wireless communications with other processors, where such one or more processor can be configured to operate on one or more processor-controlled devices that can be similar or different devices. Furthermore, references to memory, unless otherwise specified, can include one or more processor-readable and accessible memory elements and/or components that can be internal to the processor-controlled device, external to the processor-controlled device, and can be accessed via a wired or wireless network using a variety of communications protocols, and unless otherwise specified, can be arranged to include a combination of external and internal memory devices, where such memory can be contiguous and/or partitioned based on the application. Accordingly, references to a database can be understood to include one or more memory associations, where such references can include commercially available database products (e.g., SQL, Informix, Oracle) and also proprietary databases, and may also include other structures for associating memory such as links, queues, graphs, trees, with such structures provided for illustration and not limitation.

References to a network, unless provided otherwise, can include one or more intranets and/or the internet. References herein to microprocessor instructions or microprocessor-executable instructions, in accordance with the above, can be understood to include programmable hardware.

Although the disclosed embodiments included electronic paper and FOLED as flexible displays, other display types can be used for the methods and systems provided herein. For example, electro-osmotic, electropheric, retroreflective electropheric displays, etc., can be used. Accordingly, an embodiment utilizing electronic ink can be implemented based on U.S. Pat. No. 6,120,588, incorporated herein by reference in its entirety. Also incorporated herein by reference in their entirety for purposes of additional and/or optional embodiments of the key display include U.S. Pat. Nos. 6,120,839, 6,017,584, 6,067,185, 6,130,774, 6,262,706, 6,300,932, 6,323,989, and 6,327,072.

Many additional changes in the details, materials, and arrangement of parts, herein described and illustrated, can be made by those skilled in the art. Accordingly, it will be understood that the following claims are not to be limited to the embodiments disclosed herein, can include practices otherwise than specifically described, and are to be interpreted as broadly as allowed under the law.

What is claimed is:

1. A system, comprising:
a key-using device having at least one key and a microprocessor, the at least one key comprising a flexible display module, the at least one key in communications with the microprocessor,
where the microprocessor includes instructions for controlling the appearance of the flexible display module based on at least one of an application and a user profile.

2. A system according to claim 1, where the flexible display module is comprised of at least one of electronic paper and an optical organic light emitting device (OLED).

3. A system according to claim 2, where the OLED is a flexible OLED.

4. A system according to claim 1, where the at least one key includes at least one of: a light source and a transparent cover.

5. A system according to claim 1, where the instructions to control include instructions to provide a preset.

6. A system according to claim 1, where the instructions to control include instructions to display at least one of: at least one character, text, at least one sign, at least one icon, at least one symbol, at least one image, and a blank image.

7. A system according to claim 1, where the key-using device includes at least one of: a keyboard, a keypad, a computer, a cellular phone, a hand held computer, a PDA, a portable Internet device, a pager, a remote control, and a calculator.

8. A system according to claim 1, where the communications are at least one of wired and wireless.

9. A system according to claim 1, further comprising microprocessor instructions for controlling at least one operational characteristics of the at least one key.

10. A system according to claim 9, where the operational characteristics include at least one action, and the at least one action comprises at least one of: at least one electrical action, at least one audible action, at least one wired communication, at least one wireless communication, and at least one microprocessor-executable instruction.

11. A system according to claim 9, where the operational characteristics include at least one of: quick dial, display of at least one menu, generation of one or more telephone tones, mute, hold, conference, intercom, speaker, performance of at least one computation, performance of at least one calculation, transmission of at least one audio signal, generation of at least one electrical signal, macro execution, and execution of at least one microprocessor-executable instruction.

12. A system according to claim 1, where the application can include at least one microprocessor executable instruction, and the at least one microprocessor executable instruction is executed by at least one of: the microprocessor, and at least one distinct second microprocessor in communications with the microprocessor.

13. A system according to claim 1, where the user profile can be associated with at least one of a user name, a password, a personal identification number (PIN), identity information, and biometric data.

14. A system according to claim 1, where the user profile can be associated with at least one of: at least one preset and at least one default settings for the at least one key.

15. A system according to claim 14, where the at least one preset includes at least one of: at least one display and at least one operational characteristic.

16. A system according to claim 14, where the at least one preset is associated with an application.

17. A system according to claim 1, where the user profile is associated with an application.
